(19) United States
(12) Patent Application Publication
(10) Pub. No.: US 2020/0012157 A1
(43) Pub. Date: Jan. 9, 2020

(54) METHOD AND APPARATUS FOR MANUFACTURING DISPLAY PANEL

(71) Applicant: HKC Corporation Limited, Shenzhen City, Guangdong (CN)

(72) Inventor: Beizhou HUANG, Shenzhen City, Guangdong (CN)

(21) Appl. No.: 16/329,173

(22) PCT Filed: Oct. 15, 2018
(86) PCT No.: PCT/CN2018/110201

§ 371 Date: Feb. 27, 2019

(30) Foreign Application Priority Data
Sep. 25, 2017 (CN) 201710876312.2

(51) Int. Cl. G02F 1/1337; G02F 1/1333; G03F 7/20; G03F 7/26

(52) U.S. Cl. CPC G02F 1/133788; G02F 1/133351; H01L 27/32; G03F 7/26; G03F 7/20

(57) ABSTRACT

This application provides a method and an apparatus for manufacturing a display panel. The method for manufacturing a display panel includes: providing a substrate, coated with a component forming material, and divided into a plurality of component forming areas; arranging a light shielding board between the substrate and a light source, the light shielding board including a plurality of light transmission areas, the positions of the plurality of light transmission areas corresponding to the plurality of component forming areas respectively, and the plurality of light transmission areas having a same light transmittance, different light transmittances, or partially same light transmittances; and exposing and developing the substrate, light from the light source being irradiated onto the substrate through the light shielding board.

### BACKGROUND

### Technical Field

This application relates to a method for designing a display panel, and in particular, to a method and an apparatus for manufacturing a display panel.

### Related Art

With development and advancement of science and technologies, a liquid crystal display (LCD) becomes a mainstream display product and has been widely applied due to advantages such as thin frame, power saving, and low radiation. Most of LCDs on the current market are backlight LCDs, and each backlight LCD includes a liquid crystal display panel and a backlight module.

A liquid crystal display panel usually includes a color-filter (CF) substrate, a thin film transistor array substrate (TFT array substrate) and a liquid crystal layer (LC Layer) arranged between the two substrates, and the working principle of liquid crystal display panel is to control rotation of liquid crystal molecules of the liquid crystal layer by applying a driving voltage to two glass substrates, and refract the light of the backlight module to generate a picture.

A thin film transistor-liquid crystal display (TFT-LCD) has gradually dominated the display field at present due to performance such as low power consumption, excellent picture quality, and high production yield.

A display panel used in the display is usually obtained by performing an alignment operation on a parent glass substrate and performing a cutting operation. However, in a normal condition, a factory usually produces more than one product. If various types of products need to be produced during a same time period, a light source needs to be changed frequently because each product usually requires a different pre-tilt angle, and correspondingly, each product requires a different light source, especially requires a different intensity of the light source. However, it takes much time to change a light source and adjust relevant devices, resulting in low production efficiency.

### SUMMARY

To resolve the foregoing technical problem, an objective if this application is to provide a method for designing a display panel, and in particular, a method and an apparatus for manufacturing a display panel, so that two products designed by Multi-Model on Glass can both have optimal pre-tilt angles.

The objective of this application can be achieved and the technical problem of this application can be resolved through the following technical solution. A method for manufacturing a display panel provided according to this application comprises: providing a substrate, coated with a component forming material, and divided into a plurality of component forming areas; arranging a light shielding board between the substrate and a light source, the light shielding board comprising a plurality of light transmission areas, positions of the plurality of light transmission areas corresponding to the plurality of component forming areas respectively, and the plurality of light transmission areas having a same light transmittance, different light transmittance, or partially same light transmittances; and exposing and developing the substrate, light from the light source being irradiated onto the substrate through the light shielding board.

The objective of this application can be achieved and the technical problem of this application can be resolved through the following technical measure.

Another objective of this application is to provide a method for manufacturing a display panel, comprising: providing a substrate, coated with a component forming material, and divided into a plurality of component forming areas; arranging a light shielding board between the substrate and a light source, the light shielding board comprising a plurality of light transmission areas, positions of the plurality of light transmission areas corresponding to the plurality of component forming areas respectively, and the plurality of light transmission areas having a same light transmittance, different light transmittance, or partially same light transmittances; exposing and developing the substrate; and cutting the substrate, so as to obtain a plurality of display panels, light from the light source being irradiated onto the substrate through the light shielding board, and the substrate being an array substrate or a color filter layer substrate.

A yet another objective of this application is to provide an apparatus for manufacturing a display panel, comprising: an installation unit, configured to place a substrate; a coating unit, configured to coat an alignment material; a light source, configured to expose and develop the substrate to form an alignment layer; a light shielding board, disposed between the installation unit and a light source, a light transmittance of the light shielding board being controllable; and a cutting unit, configured to cut the aligned substrate, so as to obtain a plurality of display panels.

In an embodiment of this application, each of the light transmission areas comprises: a transparent area, a light shielding area, and a semi-transparent area, wherein a light transmittance of the semi-transparent area is between a light transmittance of the light transmission area and a light transmittance of the light shielding area.

In an embodiment of this application, a light transmittance of the light shielding board is adjusted according to a mixing and distribution density of a low reflective material, so that the light transmittance of the semi-transparent area is lower than the light transmittance of the transparent area, and is higher than the light transmittance of the light shielding area.

In an embodiment of this application, a material of the low reflective material is selected from a group consisting of a chromium metal and compounds thereof.

In an embodiment of this application, the light transmittance of the semi-transparent area is in a range of 30% to 70%.

In an embodiment of this application, the light shielding board is a liquid crystal laminated board, and the plurality of light transmission areas is liquid crystal layers of different concentrations respectively.

In an embodiment of this application, the substrate comprises a plurality of divided areas, and each of the divided areas comprises more than one of the component forming areas.

In an embodiment of this application, the light shielding board has a light shielding graphic layer for controlling the light transmittance; the light shielding board is detachable or the light shielding graphic layer is replaceable. The light shielding board comprises at least two different areas, and each of the areas comprises a light shielding graphic layer with a different light transmittance.

This application enables two products designed by Multi-Model on Glass to obtain optimal pre-tilt angles.

### BRIEF DESCRIPTION OF THE DRAWINGS

FIG. 1 is a schematic comparison diagram of exemplary Multi-Model on Glass and Single Model on Glass;

FIG. 2 is a schematic diagram of exemplary Multi-Model on Glass;

FIG. 3 is a schematic diagram of an apparatus for manufacturing a display panel according to an embodiment of this application;

FIG. 4 is a schematic diagram of a light shielding board according to an embodiment of this application;

FIG. 5 is a schematic diagram of manufacturing Multi-Model on Glass of a display panel according to an embodiment of this application; and

FIG. 6 is a flowchart of a method for manufacturing a display panel according to an embodiment of this application.

### DETAILED DESCRIPTION

The following embodiments are described with reference to the accompanying drawings, which are used to exemplify specific embodiments for implementation of this application. Terms about directions mentioned in this application, such as “on”, “below”, “front”, “back”, “left”, “right”, “in”, “out”, and “side surface” merely refer to directions in the accompanying drawings. Therefore, the used terms about directions are used to describe and understand this application, and are not intended to limit this application.

The accompanying drawings and the description are considered to be essentially exemplary, rather than limitative. In the figures, units with similar structures are represented by using the same reference number. In addition, for understanding and ease of description, the size and the thickness of each component shown in the accompanying drawings are arbitrarily shown, but this application is not limited thereto.

In the accompanying drawings, for clarity, thicknesses of a layer, a film, a panel, an area, and the like are enlarged. In the accompanying drawings, for understanding and ease of description, thicknesses of some layers and areas are enlarged. It should be understood that when a component such as a layer, a film, an area, or a base is described to be “on” “another component”, the component may be directly on the another component, or there may be an intermediate component.

In addition, throughout this specification, unless otherwise explicitly described to have an opposite meaning, the word “include” is understood as including the component, but not excluding any other component. In addition, throughout the specification, “on” means that one is located above or below a target component and does not necessarily mean that one is located on the top based on a gravity direction.

To further describe the technical measures taken in this application to achieve the intended application objective and effects thereof, specific implementations, structures, features, and effects of a method and an apparatus for manufacturing a display panel provided according to this application are described below in detail with reference to the accompanying drawings and specific embodiments.

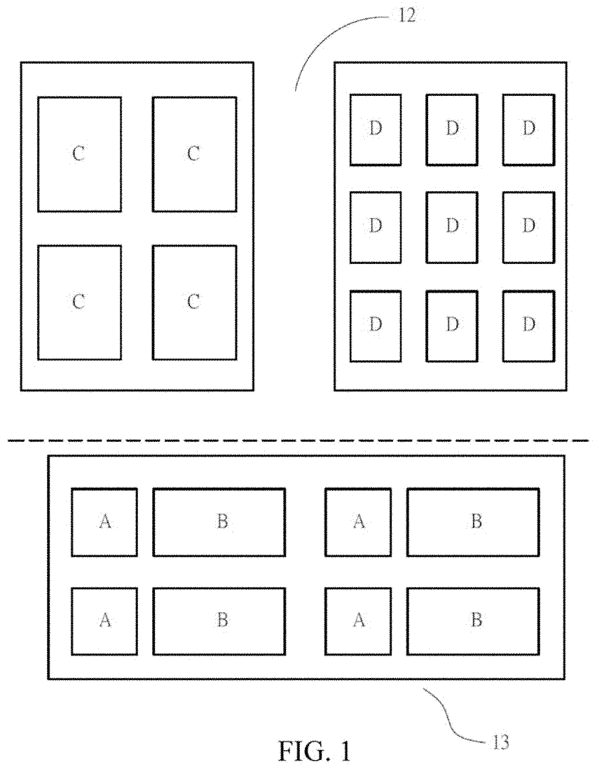

FIG. 1 is a schematic comparison diagram of exemplary Multi-Model on Glass and Single Model on Glass. Referring to FIG. 1, two upper pictures show Single Model on Glass 12 (for example, a product C or D), and one lower picture shows Multi-Model on Glass 13. The Multi-Model on Glass is named relative to the Single Model on Glass, and is briefly referred to as MMG. Products of different sizes or specifications are designed and produced on one substrate, the utilization rate of the substrate for the MMG products is high, thereby reducing waste, products of different sizes meeting market demands can be designed, and costs are reduced.

An MMG product has a difficulty that a shared process parameter cannot be found to enable the performance of two products to be optimized at the same time. Especially when aperture ratios of two products are significantly different (as shown in FIG. 1, the sizes of products A and B are different, and if the products A and B have the same resolution, a pixel aperture ratio of the product A is far less than a pixel aperture ratio of the product B), under a technical condition of optical alignment, a same process parameter can form different pre-tilt angles because amounts of ultraviolet irradiation received by the products A and B are different, and a pre-tilt angle directly affects a contract and a response time of a product. Process parameters related to a pre-tilt angle include: a liquid crystal characteristic, an ultraviolet intensity, an irrigation time, and a voltage difference between an upper display panel and a lower display panel (a CF panel and an array panel).

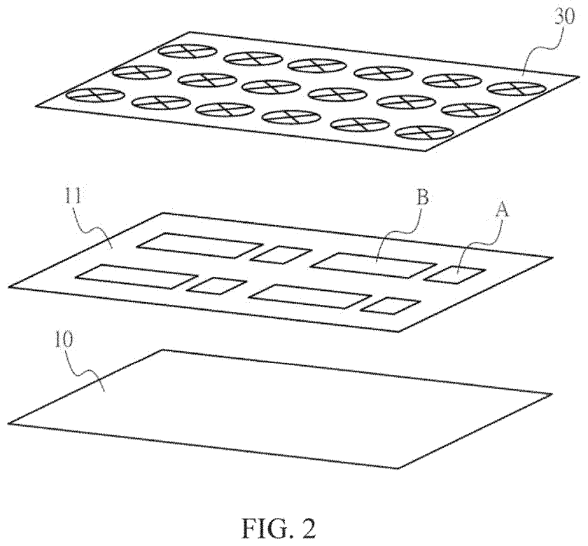

FIG. 2 is a schematic diagram of exemplary Multi-Model on Glass. Two products corresponding to a first area A and a second area B in FIG. 2 obtain a same ultraviolet irradiation intensity under same ultraviolet irradiation, thereby forming a same pre-tilt angle, that is, the polymer-stabilized vertically aligned (PSVA) products are irradiated by ultraviolet at a same time when a pre-tilt angles is formed, the obtained light intensities are also the same.

If the expected pre-tilt angles of two products corresponding to the first area A and the second area B are different, because a same light source is used and a pre-tilt angle is related to light intensity obtained by the display panel, the pre-tilt angle formed by the display panel cannot meet the expected requirements.

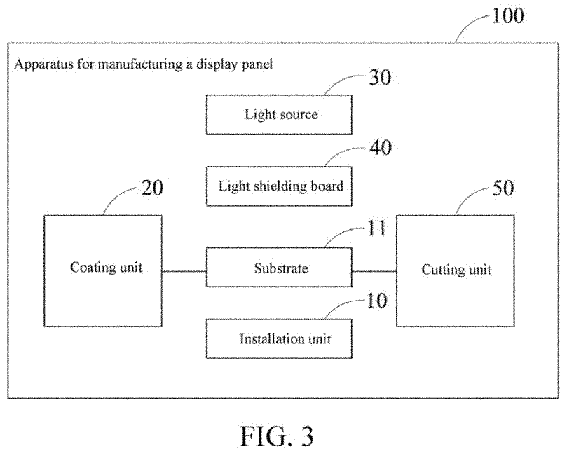

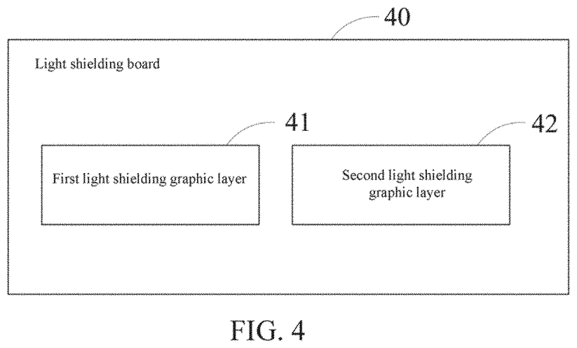

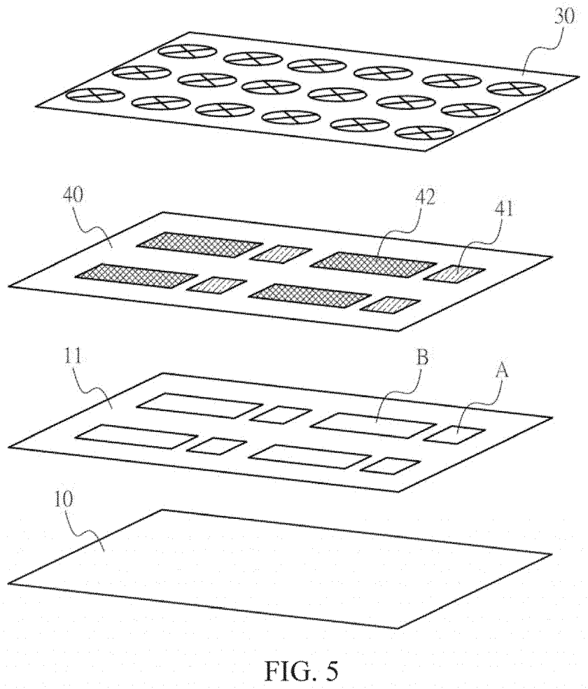

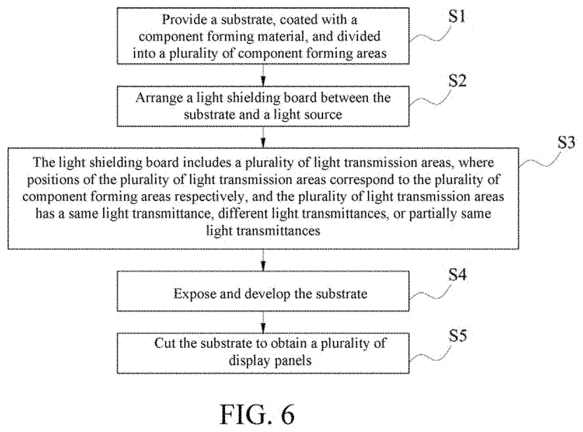

FIG. 3 is a schematic diagram of an apparatus for manufacturing a display panel according to an embodiment of this application, FIG. 4 is a schematic diagram of a light shielding board according to an embodiment of this application, FIG. 5 is a schematic diagram of manufacturing Multi-Model on Glass of a display panel according to an embodiment of this application, and FIG. 6 is a flowchart of a method for manufacturing a display panel according to an embodiment of this application. Referring to FIG. 3, FIG. 4, and FIG. 5, in an embodiment of this application, an apparatus 100 for manufacturing a display panel includes an installation unit 10, configured to place a substrate 11; a coating unit 20, configured to coat an alignment material; a light source 30, configured to expose and develop the substrate 11 to form an alignment layer; a light shielding board 40 (for example, a liquid crystal board), disposed between the installation unit 10 and the light source 30, a light transmittance of the light shielding board 40 being controllable; and a cutting unit 50, configured to cut the aligned substrate 11, so as to obtain a plurality of display panels.

In an embodiment of this application, the light shielding board 40 (for example, a liquid crystal board) includes light shielding graphic layers 41 and 42 for controlling the light transmittance.

In an embodiment of this application, the light shielding board 40 (for example, a multi-light transmittance board made of a low reflective material) includes light shielding graphic layers 41 and 42 for controlling the light transmittance.

In an embodiment of this application, the light shielding board 40 (for example, a liquid crystal board) is detachable or the light shielding graphic layers 41 and 42 is replaceable.

In an embodiment of this application, the light shielding board 40 (for example, a multi-light transmittance board made of a low reflective material) is detachable or the light shielding graphic layers 41 and 42 is replaceable.

In an embodiment of this application, the light shielding board 40 (for example, a liquid crystal board) includes at least two different areas, and each of the areas has the light shielding graphic layers 41 and 42 having different light transmittances correspondingly.

In an embodiment of this application, the light shielding board 40 (for example, a multi-light transmittance board made of a low reflective material) includes at least two different areas, and each of the areas has the light shielding graphic layers 41 and 42 having different light transmittances correspondingly.

In an embodiment of this application, the substrate 11 is an array substrate, and components of the substrate 11 include a group consisting of at least one of an alignment layer, an active switch, and a pixel unit.

In an embodiment of this application, the substrate 11 is a color filter layer substrate, and components of the substrate 11 include a group consisting of at least one of an alignment layer, a light shielding layer, and an electrode layer.

In an embodiment of this application, since the apparatus 100 for manufacturing a display panel includes the light shielding board 40 for controlling the light transmittance, a same light source may not be replaced or adjusted, and the light transmittance of the light shielding board 40 can be adjusted to adapt to light irradiation requirements of different panels. Furthermore, the apparatus 100 for manufacturing a display panel in this application can be used to manufacture Single Model on Glass and Multi-Model on Glass. When the apparatus 100 for manufacturing a display panel is used to manufacture a Single Model on Glass, light irradiation intensity can be rapidly adjusted to meet requirements. When the apparatus 100 for manufacturing a display panel is used to manufacture Multi-Model on Glass, if a same light source is used, different display panels can obtain different light irradiation intensities due to existence of the light shielding board 40, so as to form expected pre-tilt angles, so as to resolve the problem about the process parameter of the Multi-Model on Glass, that is, the light irradiation intensity. This application not only has a wide application range, but also can enable different display panels to obtain required light irradiation intensities, so that pre-tilt angles of products are optimal, thereby greatly improving product efficiency, reducing loss of materials as well as adjustment and improvement costs of relevant devices such as a light source, and reducing product costs.

In an embodiment of this application, the light shielding board 40 (for example, a liquid crystal board or a multi-light transmittance board made of a low reflective material) can be made with an unchangeable light transmittance, but can be detached to be replaced with a different light shielding board 40 to adapt to production requirements. Certainly, the light transmittance of the light shielding board 40 may be adjusted alternatively by using units such as the light shielding graphic layers 41 and 42. In such a situation, the light shielding graphic layers 41 and 42 are replaceable. the light shielding graphic layers 41 and 42 having different light transmittances, sizes, or shapes are replaced according to different products to adapt to different product requirements of display panels. Furthermore, the light shielding board 40 can have one or more light shielding graphic layers 41 and one or more light shielding graphic layers 42.

In an embodiment of this application, the light shielding board 40 (for example, a liquid crystal board or a multi-light transmittance board made of a low reflective material) includes at least two different areas (can include a first area A and a second area B in the figure), and each of the areas has a light shielding graphic layer having a different light transmittance correspondingly (that is, the first light shielding graphic layer 41 corresponding to the area A and the second light shielding graphic layer 42 corresponding to the area B).

In an embodiment of this application, the sizes and shapes of each of the areas are adjusted by changing the light shielding board 40 (for example, a liquid crystal board or a multi-light transmittance board made of a low reflective material) or the light shielding graphic layers 41 and 42. In the apparatus 100 for manufacturing a display panel, the light shielding board 40 may have a plurality of different areas, and the sizes of the areas correspond to a size of a display panel, so as to adapt to the requirements of Multi-Model on Glass (more than two display panels are manufactured at the same time). Furthermore, the sizes, shapes, and the light transmittances of the areas all can be adjusted. For example, if a product A is small while a product B is big, the light shielding board may be designed to have two areas having different sizes, and certainly, the light transmittances of the different areas also correspond to the display panel.

In an embodiment of this application, the substrate 11 is divided into different areas for different display panels, and the light shielding board 40 has light shielding graphic layers 41 and 42 having different light transmittances for different areas. The light transmittances of the light shielding graphic layers 41 and 42 are set according to aperture ratios of the display panels, and a light transmittance is inversely proportional to an aperture ratio of a display panel. In this embodiment, the light shielding board 40 has different areas actually because the substrate 11 is also divided into different areas for different display panels, and the light shielding board 40 is set and adjusted according to an area and a display panel in an area.

Referring to FIG. 3 and FIG. 6, in an embodiment of this application, a method for manufacturing a display panel includes: providing a substrate 11, coated with a component forming material, and divided into a plurality of component forming areas; arranging a light shielding board 40 between the substrate 11 and a light source 30, the light shielding board 40 including a plurality of light transmission areas, positions of the plurality of light transmission areas corresponding to the plurality of component forming areas respectively, and the plurality of light transmission areas having a same light transmittance, different light transmittances, or partially same light transmittances; exposing and developing the substrate 11; and cutting the substrate 11 to obtain a plurality of display panels. Light from the light source 30 is irradiated onto the substrate 11 through the light shielding board 40, and the substrate 11 is an array substrate or a color filter layer substrate.

In an embodiment of this application, each of the light transmission areas includes a transparent area, a light shielding area, and a semi-transparent area, and a light transmittance of the semi-transparent area is between a light transmittance of the transparent area and a light transmittance of the light shielding area.

In an embodiment of this application, the light transmittance of the light shielding board is adjusted according to a mixing and distribution density of a low reflective material, so that the light transmittance of the semi-transparent area is lower than the light transmittance of the transparent area, and is higher than the light transmittance of the light shielding area.

In an embodiment of this application, a material of the low reflective material is selected from a group consisting of a chromium metal and compounds thereof.

In an embodiment of this application, the light transmittance of the semi-transparent area is in a range of 30% to 70%.

In an embodiment of this application, the light shielding board is a liquid crystal laminated board, and the plurality of light transmission areas is liquid crystal layers of different concentrations respectively

In an embodiment of this application, the light shielding board is a multi-light transmittance board made of a low reflective material, and the plurality of light transmission areas is a multi-light transmittance layer made of a low reflective material at different proportions respectively.

In an embodiment of this application, the substrate includes a plurality of divided areas, and each of the divided areas includes more than one component forming areas.

Referring to FIG. 6, in a procedure S1, a substrate is provided, where the substrate is coated with a component forming material, and is divided into a plurality of component forming areas.

Referring to FIG. 6, in a procedure S2, a light shielding board is arranged between the substrate and a light source.

Referring to FIG. 6, in a procedure S3, the light shielding board includes a plurality of light transmission areas, where positions of the plurality of light transmission areas respectively correspond to the plurality of component forming areas, and the plurality of light transmission areas has a same light transmittance, different light transmittances, or partially same light transmittances.

Referring to FIG. 6, in a procedure S4, the substrate is exposed and developed.

Referring to FIG. 6, in a procedure S5, the substrate is cut to obtain a plurality of display panels.

In some embodiments, the display panel in this application may be, but is not limited to, for example, a liquid crystal display panel, and may alternatively be a organic light emitting diode (OLED) display panel, a white OLED display panel, a quantum-dot LED display panel, a plasma display panel, a curved display panel, or another type of display panel.

This application enables two products designed by the Multi-Model on Glass to obtain optimal pre-tilt angles.

The wordings such as “in some embodiments” and “in various embodiments” are repeatedly used. The wordings usually refer to different embodiments, but they may also refer to a same embodiment. The words, such as “comprise”, “have”, and “include”, are synonyms, unless other meanings are indicated in the context thereof.

The foregoing descriptions are merely preferred embodiments of this application, and are not intended to limit this application in any form. Although this application has been disclosed above through the preferred embodiments, the embodiments are not intended to limit this application. Any person skilled in the art can make some variations or modifications, which are equivalent changes, according to the foregoing disclosed technical content to obtain equivalent embodiments without departing from the scope of the technical solutions of this application. Any simple amendment, equivalent change, or modification made to the foregoing embodiments according to the technical essence of this application without departing from the content of the technical solutions of this application shall fall within the scope of the technical solutions of this application.

What is claimed is:

1. A method for manufacturing a display panel, comprising:
providing a substrate, coated with a component forming material, and divided into a plurality of component forming areas;
arranging a light shielding board between the substrate and a light source, wherein the light shielding board comprises a plurality of light transmission areas, positions of the plurality of light transmission areas respectively correspond to the plurality of component forming areas, and the plurality of light transmission areas has a same light transmittance, different light transmittances, or partially same light transmittances; and
exposing and developing the substrate, wherein light from the light source is irradiated onto the substrate through the light shielding board.

2. The method for manufacturing a display panel according to claim 1, wherein each of the light transmission areas comprises a transparent area, a light shielding area, and a semi-transparent area.

3. The method for manufacturing a display panel according to claim 2, wherein a light transmittance of the semi-transparent area is between a light transmittance of the transparent area and a light transmittance of the light shielding area.

4. The method for manufacturing a display panel according to claim 3, wherein a light transmittance of the light shielding board is adjusted according to a mixing and distribution density of a low reflective material, so that the light transmittance of the semi-transparent area is lower than the light transmittance of the transparent area, and is higher than the light transmittance of the light shielding area.

5. The method for manufacturing a display panel according to claim 3, wherein a material of the low reflective material is selected from a group consisting of a chromium metal and compounds thereof.

6. The method for manufacturing a display panel according to claim 2, wherein the light transmittance of the semi-transparent area is in a range of 30% to 70%.

7. The method for manufacturing a display panel according to claim 1, wherein the light shielding board is a liquid crystal laminated board.

8. The method for manufacturing a display panel according to claim 7, wherein the plurality of light transmission areas is liquid crystal layers of different concentrations respectively.

9. The method for manufacturing a display panel according to claim 1, wherein the substrate comprises a plurality of divided areas.

10. The method for manufacturing a display panel according to claim 9, wherein each of the divided areas comprises more than one of the component forming areas.

11. The method for manufacturing a display panel according to claim 1, wherein the substrate is an array substrate.

12. The method for manufacturing a display panel according to claim 1, wherein the substrate is a color filter layer substrate.

13. A method for manufacturing a display panel, comprising:
providing a substrate, coated with a component forming material, and divided into a plurality of component forming areas;
arranging a light shielding board between the substrate and a light source, wherein the light shielding board comprises a plurality of light transmission areas, positions of the plurality of light transmission areas correspond to the plurality of component forming areas respectively, and the plurality of light transmission areas has a same light transmittance, different light transmittances, or partially same light transmittances;
exposing and developing the substrate; and
cutting the substrate to obtain a plurality of display panels, wherein
light from the light source is irradiated onto the substrate through the light shielding board.

14. An apparatus for manufacturing a display panel, comprising:
an installation unit, configured to place a substrate;
a coating unit, configured to coat an alignment material;
a light source, configured to expose and develop the substrate to form an alignment layer;
a light shielding board, disposed between the installation unit and a light source, wherein a light transmittance of the light shielding board is controllable; and
a cutting unit, configured to cut the aligned substrate, so as to obtain a plurality of display panels.

15. The apparatus for manufacturing a display panel according to claim 14, wherein the light shielding board comprises a light shielding graphic layer for controlling the light transmittance.

16. The apparatus for manufacturing a display panel according to claim 15, wherein the light shielding board is detachable or the light shielding graphic layer is replaceable.

17. The apparatus for manufacturing a display panel according to claim 15, wherein the light shielding board comprises at least two different areas, and each of the areas comprises a light shielding graphic layer having a different light transmittance correspondingly.

18. The apparatus for manufacturing a display panel according to claim 14, wherein the substrate comprises a plurality of divided areas, and each of the divided areas comprises more than one of the component forming areas.

19. The apparatus for manufacturing a display panel according to claim 14, wherein the light shielding board is a liquid crystal laminated board, and the plurality of light transmission areas is liquid crystal layers of different concentrations respectively.

20. The apparatus for manufacturing a display panel according to claim 14, wherein the substrate is an array substrate or a color filter layer substrate.
